(19) United States
(12) Patent Application Publication
(10) Pub. No.: US 2007/0124628 A1
(43) Pub. Date: May 31, 2007

(54) Methods of memory bitmap verification for finished product

(75) Inventors: David T. Price, Gresham, OR (US); Mark Ward, West Linn, OR (US); Jayashree Kalpathy-Cramer, West Linn, OR (US)

Correspondence Address: LSI LOGIC CORPORATION, 1621 BARBER LANE, MS: D-106, MILPITAS, CA, 95035, US

(73) Assignee: LSI Logic Corporation

(21) Appl. No.: 11/290,178

(22) Filed: Nov. 30, 2005

(51) Int. Cl. G11C 29/00

(52) U.S. Cl. 714/718

(57) ABSTRACT

Improved methods for verifying that a physical location of a memory matches a design logical representation, without having to use a focused ion beam to physically damage a memory location. A first method provides that EMMI is used to identify the physical location of a failing memory bit. A second method provides that a physical location is damaged with a laser, as is used to open hard wired fuses, and then the DUT is electrically tested and the memory built in self test (MEM BIST) repair is used to identify the logical address for the damaged region. A third method provides that a physical location is damaged using an electrical test on the ATE that causes an onboard fuse element in the memory arrays to be broken through the application of a high voltage.

### Background

The present invention generally relates to methods for performing failure analysis of semiconductor memory, and more specifically relates to a method for performing logical to physical verification of semiconductor memory by intentionally creating an electrical design “defect” within the physical representation of a design layout.

During the failure analysis of semiconductor memory, it is necessary to know the physical location of a failing memory bit, but typically what is available from the design is merely the design logical representation of the failing bit. Once the logical location is determined, a scramble equation is used to identify the physical location of the failing bit, based on the logical location. As such, the scramble equation effectively converts the logical location to the physical location of the failing bit. However, often there are errors in the scramble mapping. As a result, there is a need to physically verify that the determined physical location is correct. If this verification is not performed, then failure analysis will subsequently be performed on the incorrect memory location, incurring extra delays and costs.

Currently, the typical method to verify that the calculated physical location is correct is to use a focused ion beam (FIB) to physically damage that particular memory location and then retest it. FIG. 1 provides a flow diagram which illustrates the typical method in more detail. As shown, the process is started (bubble 100 in FIG. 1) and initially a package unit, such as a flip-chip package, is decapped (block 102 in FIG. 1). Then, design layout CAD files are accessed to identify circuitry in the memory area of interest (block 104 in FIG. 1). Then, a focused ion beam (FIB) and the CAD software are used to navigate through the backside of the silicon and physically damage the identified location (block 106 in FIG. 1). Subsequently, electrical verification is performed on the Automated Test Equipment (ATE) to confirm that the electrical address matches the physical site which was damaged using the focused ion beam (block 108 in FIG. 1). If the electrical results indicate that the electrical address matches the physical site which was damaged (diamond 110 in FIG. 1), the process is ended (bubble 112 in FIG. 1). Otherwise, the focused ion beam (FIB) and the CAD software are used to navigate through the backside of the silicon and physically damage another location (block 106 in FIG. 1), and electrical verification is again performed on the Automated Test Equipment (ATE) to confirm that the electrical address matches the physical site which was damaged using the focused ion beam (block 108 in FIG. 1), and so on.

The disadvantages of using a focused ion beam to physically damage memory locations in order to verify that a calculated physical location matches a design logical representation include, but may not be limited to, the following: the process is costly; it takes a long time to make the focused ion beam cut, and the focused ion beam is typically a limited availability tool; the package trend for complex ASIC designs is to use flip-chip packaging, and using a focused ion beam to navigate through the backside of the silicon and physically damage a memory location is difficult and may require several attempts; and if the electrical re-test result does not correspond with the damaged location, then this operation may be required to be repeated over several iterations (and possibly several new units) causing costly delays and engineering resources.

### OBJECTS AND SUMMARY

An object of an embodiment of the present invention is to provide an improved method for verifying that a physical location of a memory matches a design logical representation.

Another object of an embodiment of the present invention is to provide a method for verifying that a physical location of a memory matches a design logical representation, without having to use a focused ion beam to physically damage a memory location.

Briefly, and in accordance with at least one of the foregoing objects, embodiments of the present invention provide method for verifying that a physical location of a memory matches a design logical representation. A first method provides that EMMI is used to identify the physical location of a failing memory bit. A second method provides that a physical location is damaged with a laser, as is used to open hard wired fuses, and then the DUT is electrically tested and the memory built in self test (MEM BIST) repair is used to identify the logical address for the damaged region. A third method provides that a physical location is damaged using an electrical test on the ATE that causes an onboard fuse element in the memory arrays to be broken through the application of a high voltage.

### BRIEF DESCRIPTION OF THE DRAWINGS

The organization and manner of the structure and operation of the invention, together with further objects and advantages thereof, may best be understood by reference to the following description, taken in connection with the accompanying drawings, wherein:

FIG. 1 provides a flow diagram which illustrates a prior art method of verifying that a physical location matches a design logical representation;

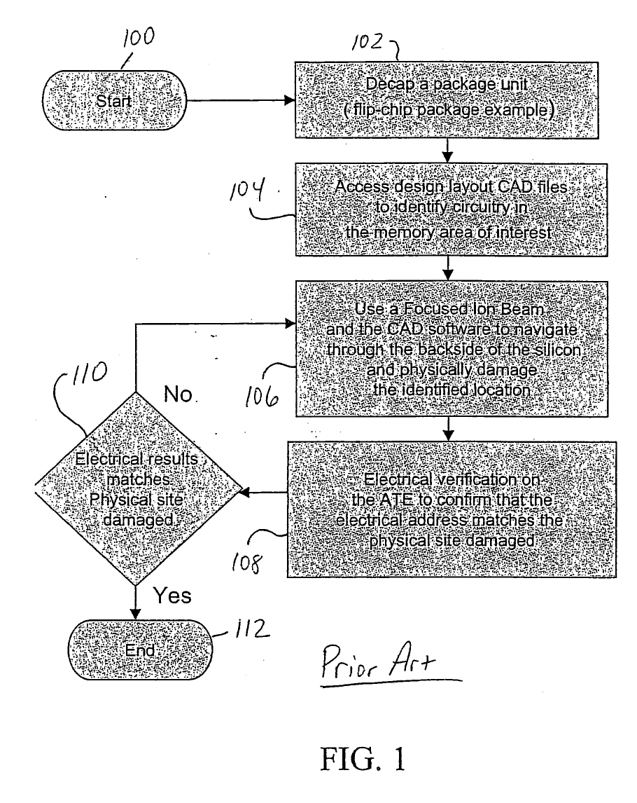

FIG. 2 provides a flow diagram which illustrates a method of verifying that a physical location matches a design logical representation, wherein the method is in accordance with an embodiment of the present invention;

FIG. 3 illustrates backside EMMI in accordance with the method shown in FIG. 2;

FIG. 4 provides a flow diagram which illustrates a method of verifying that a physical location matches a design logical representation, wherein the method is in accordance with another embodiment of the present invention;

FIG. 5 illustrates the use of a laser to damage a memory cell in accordance with the method shown in FIG. 4;

FIG. 6 provides a flow diagram which illustrates a method of verifying that a physical location matches a design logical representation, wherein the method is in accordance with yet another embodiment of the present invention; and

FIG. 7 illustrates using embedded fuses for verification in accordance with the method shown in FIG. 6.

### DESCRIPTION

While the invention may be susceptible to embodiment in different forms, there are shown in the drawings, and herein will be described in detail, specific embodiments of the invention. The present disclosure is to be considered an example of the principles of the invention, and is not intended to limit the invention to that which is illustrated and described herein.

Embodiments of the present invention provide improved methods for verifying that a physical location of a memory matches a design logical representation, without having to use a focused ion beam to physically damage a memory location.

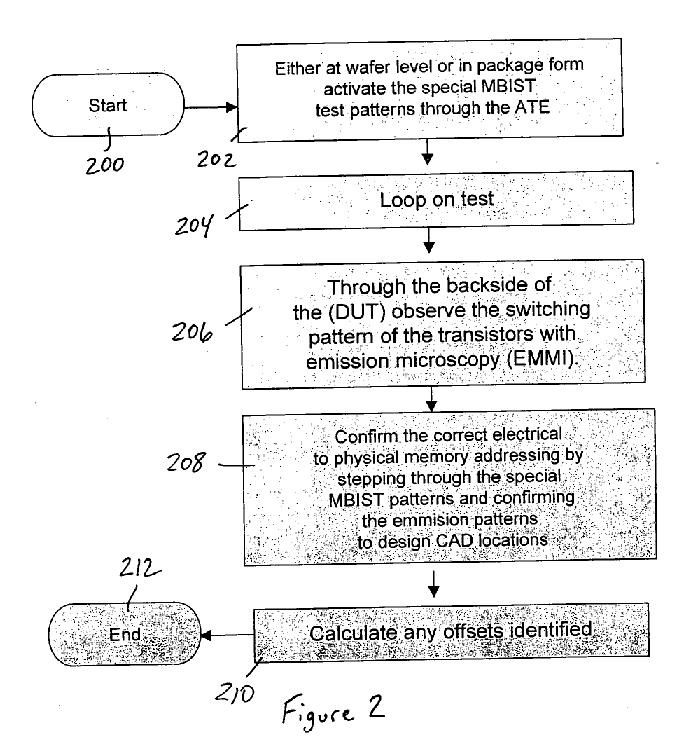

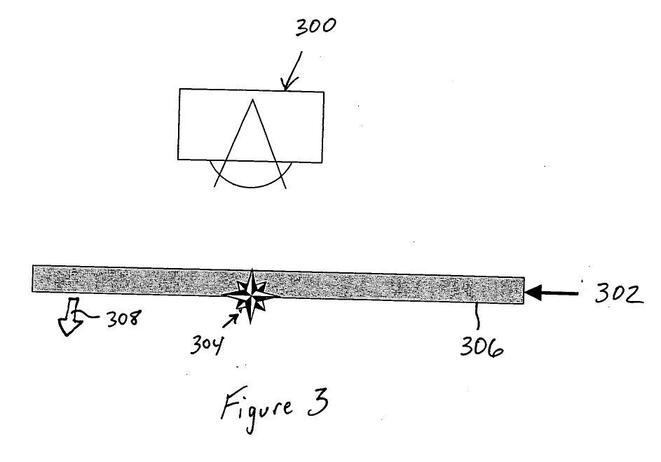

FIGS. 2 and 3 illustrate a method which is in accordance with a first embodiment of the present invention. The method provides for backside EMMI, wherein the device under test need not be damaged. This means that the same device under test that requires failure analysis can be used for physical location to logical address verification. Specifically, EMMI is used to identify the physical location of a failing memory bit rather than referencing a FIB-induced damaged site. Rather than doing physical damage to the memory cell with FIB, one observes the electrically active circuitry as a function of test pattern. Specifically, the fabricated device with memory is taken in a wafer or packaged part form and the backside if the substrate can be thinned by typical failure analysis chemical mechanical polishing techniques. Then the device under test (DUT) is electrically accessed with a tester, writing test patterns in the form of a single bit, multiple bits, an entire row, an entire column, or a combination of all of the above, to make the transistors of interest electrically toggling between logical one and zero. From the backside of the DUT, one can observe the switching transistors with emission microscopy (EMMI). The test patterns used provide the logical location and the backside EMMI can provide the physical location. For ease of use, the test pattern could be the switching of a row and column, providing a very bright EMMI emission that is easy to locate.

The test patterns for this failure analysis confirmation are preferably embedded into the existing MBIST controller and accessed through the existing JTAG port commands used for existing MBIST testing.

The backside EMMI method shown in FIGS. 2 and 3 does not require the physical damage of the DUT. This means that the same DUT that requires failure analysis can be used for physical location to logical address verification. Also, it is very common to do backside thinning of a DUT for failure analysis. If a DUT has a single bit that requires failure analysis, the part can be thinned for backside EMMI, perform the physical to logical verification and then immediately observe the single bit of interest. In addition, flip chip technology devices are common within the industry and they are packaged in such a way that makes them well suited for backside EMMI while the part is electrically addressed, since the device is packaged face down. There is no need to use expensive and time consuming FIB processing.

As shown in FIG. 2, the method provides that the process is started (bubble 200 in FIG. 2) and either at wafer level or in package form, the special MBIST test patterns are activated through the ATE (block 202 in FIG. 2). Then, the test is looped (block 204 in FIG. 2), and the switching pattern of the transistors is observed through the backside of the DUT with emission microscopy (EMMI) (block 206 in FIG. 2). Then, one confirms the correct electrical to physical memory addressing by stepping through the special MBIST patterns and confirming the emission patterns to design CAD locations (block 208 in FIG. 2), calculates any offsets which have been identified (block 210 in FIG. 2), and then the process is ended (bubble 212 in FIG. 2).

In FIG. 3, reference numeral 300 identifies the backside emission microscopy (EMMI), reference numeral 302 identifies the thinned substrate of the DUT, reference numeral 304 identifies an active memory cell emitting due to logical address access, and reference numeral 306 identifies the active side of the DUT which is connected to the ATE (represented by arrow 308).

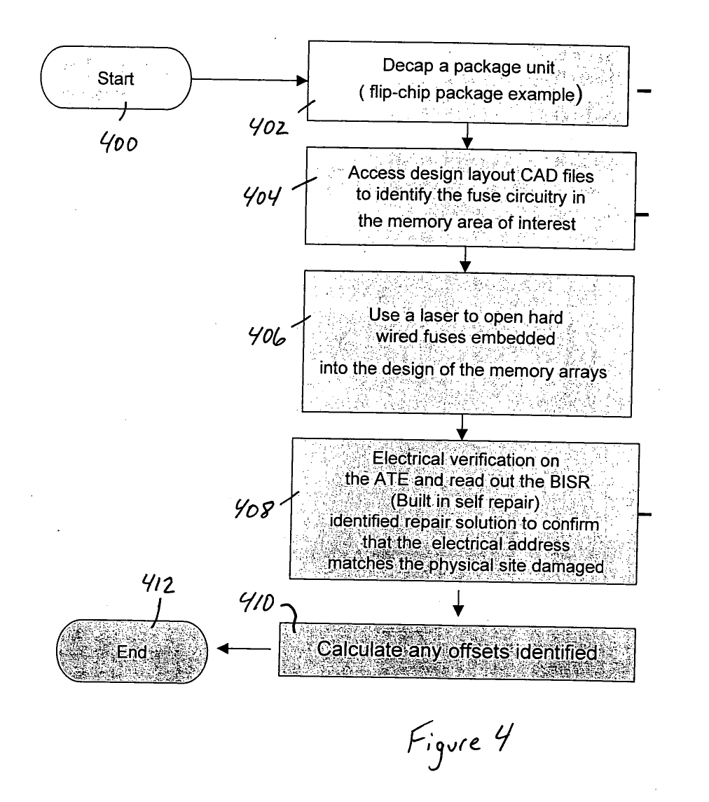

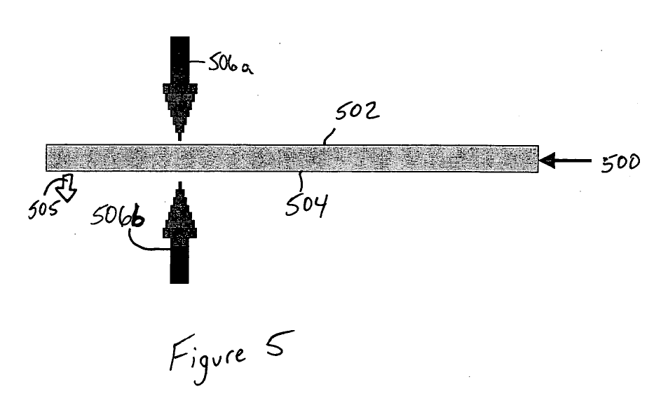

FIGS. 4 and 5 illustrate a method which is in accordance with a second embodiment of the present invention. The method provides that rather than doing physical damage to the memory cell with FIB, a physical location is damaged with a laser, as is used to open hard wired fuses. After a specified physical location is damaged with the laser, the DUT is electrically tested again and the memory built in self test (MEM BIST) repair is used to identify the logical address for the damaged region. By comparing these two, the correlation of physical location to logical address is verified. This method requires that hard wired fuse locations be added during the design stage.

The method shown in FIGS. 4 and 5 provides that rather than using a FIB to create the damage, a more readily available higher throughput laser system is used. This reduces the amount of time to do the work.

As shown in FIG. 4, the method provides that the process is started (bubble 400 in FIG. 4) and a package unit is decapped (such as a flip-chip package) (block 402 in FIG. 4). Then, design layout CAD filed are accessed to identify the fuse circuitry in the memory area of interest (block 404 in FIG. 4), and a laser is used to open hard wired fuses embedded into the design of the memory arrays (block 406 in FIG. 4). Then, one performs electrical verification on the ATE and reads out the BISR (Built in self repair) identified repair solution to confirm that the electrical address matches the physical site damaged (block 408 in FIG. 4), calculates any offsets which have been identified (block 410 in FIG. 4), and then the process is ended (bubble 412 in FIG. 4).

In FIG. 5, reference numeral 500 identifies a substrate of a DUT, wherein the backside is identified with reference numeral 502 and the front side is identified with reference numeral 504, wherein the front side 504 is the active device side and is electrically connected to ATE (represented by arrow 505). As shown in FIG. 5, a memory cell can be damaged by a laser either through the backside 502 of the substrate 500 (in which case the laser is represented by arrow 506a), or through the front side 504 of the substrate 500 (in which case the laser is represented by arrow 506b). Typically, if the laser is used to perform backside laser damage, the thickness of the substrate is thinned, wherein the thickness of the substrate can be normal in the case of front side laser damage.

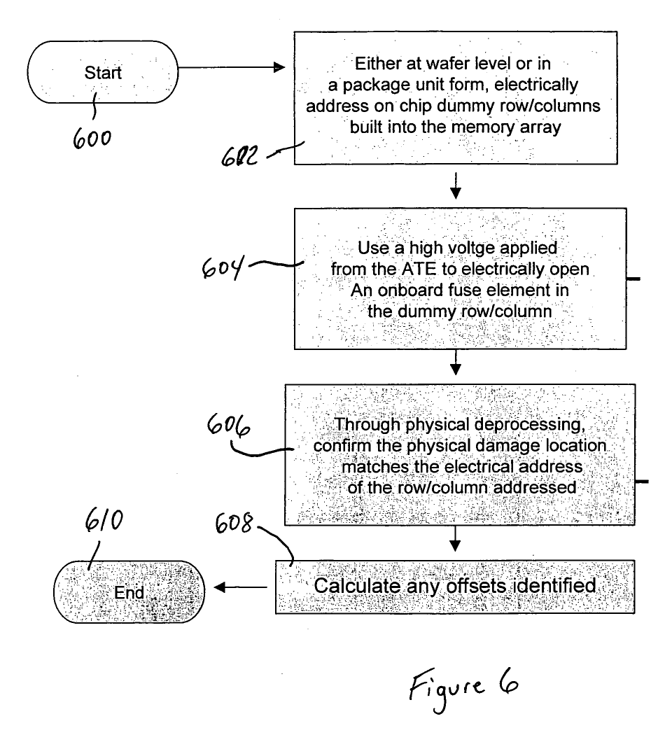

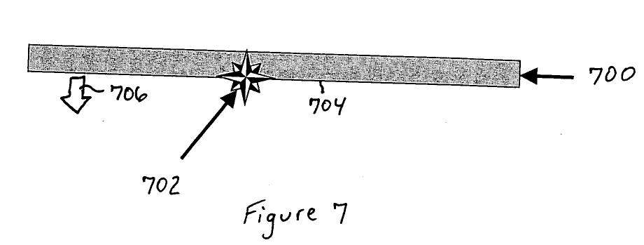

FIGS. 6 and 7 illustrate a method which is in accordance with a second embodiment of the present invention. The method provides that rather than doing physical damage to the memory cell with FIB, a physical location is damaged using an electrical test on the ATE that causes an onboard fuse element in the memory arrays to be broken through the application of a high voltage.

This electrical method provides a physical location that can then be compared to the electrical address applied in order to verify the physical to logical address/data scramble. This method requires a dummy row/column in the memory array with a fuse element that can be accessed through the ATE.

The method shown in FIGS. 6 and 7 provides that rather than using a FIB to create the damage in the memory array, the existing ATE (automatic test equipment) could be used to damage an onboard fuse element in the memory arrays. This reduces the amount of time required to verify the memory scramble.

As shown in FIG. 6, the method provides that the process is started (bubble 600 in FIG. 6) and either at wafer level or in a package unit form, one electrically addresses on chip dummy rows/columns which are built into the memory array (block 602 in FIG. 6). Then, a high voltage applied from the ATE is used to electrically open an onboard fuse element in the dummy/row column (block 604 in FIG. 6), and through physical deprocessing, it is confirmed that the physical damage location matches the electrical address of the row/column addressed (block 606 in FIG. 6). Finally, and offsets which have been identified are calculated (block 608 in FIG. 6), and then the process is ended (bubble 610 in FIG. 6).

In FIG. 7, reference numeral 700 identifies a substrate of a DUT (no thinning required), reference numeral 702 identifies an active memory cell fuse which has been damaged by intentional electrical damage, and reference numeral 704 identifies the active device side of the DUT which is electrically connected to ATE (represented by arrow 706).

While embodiments of the present invention are shown and described, it is envisioned that those skilled in the art may devise various modifications of the present invention without departing from the spirit and scope of the appended claims.

What is claimed is:

1. A method of verifying that a physical location of a memory on a DUT matches a design logical representation, said method comprising:
electrically connecting the DUT to ATE;
using the ATE to initiate a pre-determined test pattern which activates one or more transistors on the DUT;
observing emissions of the one or more transistors through a backside of the DUT;
confirming correct electrical to physical memory addressing by assessing the emissions to the test pattern.

2. A method as recited in claim 1, wherein the step of using the ATE to initiate a pre-determined test pattern comprises using the ATE to initiate MBIST test patterns.

3. A method as recited in claim 1, wherein the step of observing emissions through the backside of the DUT comprises using EMMI.

4. A method as recited in claim 2, further comprising stepping through the MBIST patterns and confirming the emission patterns to design locations.

5. A method as recited in claim 1, further comprising electrically accessing the DUT using the ATE, thereby writing test patterns in the form of a single bit, multiple bits, an entire row, an entire column, or a combination of all of the above, to make the transistors of interest electrically toggle between logical one and zero.

6. A method as recited in claim 1, wherein the ATE is used to switch a specific row and column, thereby providing a very bright EMMI emission that is easy to locate.

7. A method as recited in claim 1, wherein the test patterns are embedded into an MBIST controller and are accessed through JTAG port commands used for MBIST testing.

8. A method of verifying that a physical location of a memory on a DUT matches a design logical representation, said method comprising:
electrically connecting the DUT to ATE;
using the ATE to test the DUT;
opening at least one pre-determined hard wired fuse which is embedded into memory arrays of the DUT; and
using the ATE to electrically test the DUT and using the memory built in self test (MEM BIST) repair to identify the logical address for the damaged region.

9. A method as recited in claim 8, further comprising adding hard wired fuse locations to the DUT during a design stage.

10. A method as recited in claim 8, wherein the step of opening at least one pre-determined hard wired fuse which is embedded into memory arrays of the DUT comprises using a laser.

11. A method as recited in claim 8, wherein the step of opening at least one pre-determined hard wired fuse which is embedded into memory arrays of the DUT comprises using a laser on a backside of the DUT.

12. A method as recited in claim 8, wherein the step of opening at least one pre-determined hard wired fuse which is embedded into memory arrays of the DUT comprises using a laser on a front side of the DUT, wherein the front side is an active device side and is electrically connected to the ATE.

13. A method of verifying that a physical location of a memory on a DUT matches a design logical representation, said method comprising:
providing fuse elements on the DUT;
breaking one of the fuse elements associated with a pre-determined address;
confirming that the physical location of the broken fuse matches the pre-determined address.

14. A method as recited in claim 13, further comprising electrically connecting the DUT to ATE and wherein the step of breaking one of the fuse elements comprises using the ATE to apply a high enough voltage to the DUT that the fuse breaks.
